(19) United States
(12) Patent Application Publication
(10) Pub. No.: US 2026/0136998 A1
(43) Pub. Date: May 14, 2026

(54) SEMICONDUCTOR PACKAGE COMPRISING ADHESIVE LAYER AND METHOD OF MANUFACTURING THE SAME

(71) Applicant: Samsung Electronics Co., Ltd., Suwon-si (KR)

(72) Inventors: Haseob Seong, Suwon-si (KR); Dawoon Jung, Suwon-si (KR)

(21) Appl. No.: 19/336,600

(22) Filed: Sep. 23, 2025

(30) Foreign Application Priority Data
Nov. 12, 2024 (KR) 10-2024-0159798

(51) Int. Cl. H01L 25/065; H01L 23/00; H01L 23/28; H01L 23/48

(52) U.S. Cl. CPC H10W 90/00; H10W 20/20; H10W 74/00; H10W 72/07352; H10W 72/20; H10W 72/327

(57) ABSTRACT

A semiconductor package includes a base chip including a base substrate and upper connection terminals disposed in an upper portion of the base substrate; a semiconductor chip stack including a plurality of semiconductor chips including lower pads and upper pads stacked in order on the base chip in a first direction and opposite to each other, and having through-vias electrically connecting the lower pads to the upper pads, and the plurality of semiconductor chips include a lowermost semiconductor chip and an uppermost semiconductor chip, and the lower pads of the lowermost semiconductor chip are in contact with the upper connection terminals; a dummy chip on the semiconductor chip stack; and a plurality of adhesive layers including a first adhesive layer on the uppermost semiconductor chip and a second adhesive layer on the first adhesive layer.

### CROSS-REFERENCE TO RELATED APPLICATION(S)

This application claims benefit of priority under 35 U.S.C. § 119 to Korean Patent Application No. 10-2024-0159798 filed on Nov. 12, 2024, in the Korean Intellectual Property Office, the disclosure of which is incorporated herein by reference in its entirety.

### BACKGROUND

Example embodiments of the present disclosure relate to a semiconductor package and a method of manufacturing the same.

A semiconductor device mounted on an electronic device may be required to have miniaturization, high-performance and large-capacity. To implement this, a semiconductor package in which semiconductor chips stacked in a vertical direction are interconnected using a through-electrode (e.g., through silicon via) has been developed.

### SUMMARY

An example embodiment of the present disclosure is to provide a semiconductor package having improved reliability.

According to an example embodiment of the present disclosure, a semiconductor package includes a base chip including lower connection terminals and upper connection terminals opposite to each other, and through-electrodes electrically connecting the lower connection terminals to the upper connection terminals; a semiconductor chip stack including a plurality of semiconductor chips stacked in order on the base chip in a first direction, wherein the plurality of semiconductor chips in the semiconductor chip stack include a first semiconductor chip disposed on the base chip, and including first lower pads and first upper pads opposite to each other, and first through-vias electrically connecting the first lower pads to the first upper pads, a second semiconductor chip disposed on the first semiconductor chip, and including second lower pads and second upper pads opposite to each other, and including second through-vias electrically connecting the second lower pads to the second upper pads, a third semiconductor chip disposed on the second semiconductor chip and including front pads disposed on the front surface; a plurality of connection bumps disposed below the base chip and electrically connected to the lower connection terminals; a dummy chip on the semiconductor chip stack; and a plurality of adhesive layers between the semiconductor chip stack and the dummy chip, wherein the first lower pads of the first semiconductor chip are in contact with the upper connection terminals of the base chip adjacent to each other in the first direction, wherein the first upper pads of the first semiconductor chip are in contact with the second lower pads of the second semiconductor chip adjacent to each other in the first direction, wherein the front pads of the third semiconductor chip are in contact with the second upper pads of the second semiconductor chip adjacent to each other in the first direction, and wherein the plurality of adhesive layers include a first adhesive layer on the semiconductor chip stack and a second adhesive layer on the first adhesive layer.

According to an example embodiment of the present disclosure, a semiconductor package includes a base chip; a semiconductor chip stack including a plurality of semiconductor chips stacked in order on the base chip in a first direction; a dummy chip on the semiconductor chip stack; an adhesive layer between the semiconductor chip stack and the dummy chip; and an encapsulant covering a side surface of each of the semiconductor chip stack, the dummy chip, and the adhesive layer on the base chip, wherein the adhesive layer includes an extension portion extending in a second direction perpendicular to the first direction between the semiconductor chip stack and the dummy chip and a plurality of fillet portions connected to the extension portion and extending to the encapsulant, wherein the plurality of fillet portions include a first fillet portion extending from a lower region of the extension portion into the encapsulant; and a second fillet portion extending from an upper region of the extension portion into the encapsulant.

According to an example embodiment of the present disclosure, a semiconductor package includes a base chip including a base substrate and upper connection terminals disposed in an upper portion of the base substrate; a semiconductor chip stack including a plurality of semiconductor chips stacked in order on the base chip in a first direction, each of the plurality of semiconductor chips including lower pads and upper pads opposite to each other and having through-vias electrically connecting the lower pads to the upper pads, wherein the plurality of semiconductor chips include a lowermost semiconductor chip and an uppermost semiconductor chip, and the lower pads of the lowermost semiconductor chip are in contact with the upper connection terminals; a dummy chip on the semiconductor chip stack; and a plurality of adhesive layers including a first adhesive layer on the uppermost semiconductor chip and a second adhesive layer on the first adhesive layer.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor package according to an example embodiment of the present disclosure;

FIG. 2A is a cross-sectional diagram illustrating a semiconductor package taken along line I-I′ in FIG. 1;

FIG. 2B is an enlarged diagram illustrating region ‘A’ illustrated in FIG. 2A;

FIG. 2C is an enlarged diagram illustrating region ‘B’ illustrated in FIG. 2A;

FIGS. 3A to 3D are enlarged diagrams illustrating a portion of a semiconductor package according to a modified example of the present disclosure, illustrating region ‘B’ in FIG. 2A;

FIG. 4 is a cross-sectional diagram taken along line I-I′ in FIG. 1;

FIG. 5 is a plan diagram illustrating a semiconductor package according to an example embodiment of the present disclosure;

FIG. 6A is a cross-sectional diagram illustrating a semiconductor package taken along line I-I′ in FIG. 5;

FIG. 6B is an enlarged diagram illustrating region ‘C’ in FIG. 6A;

FIG. 7 is an enlarged diagram illustrating a semiconductor package according to a modified example of the present disclosure, illustrating region ‘C’ in FIG. 6A;

FIG. 8A is a plan diagram illustrating a semiconductor package according to an example embodiment of the present disclosure;

FIG. 8B is a cross-sectional diagram illustrating a semiconductor package taken along line II-II′ in FIG. 8A;

FIGS. 9 to 12 are cross-sectional diagrams illustrating processes of a method of manufacturing a semiconductor package in order according to an example embodiment of the present disclosure; and

FIG. 13 is a cross-sectional diagram illustrating processes of a method of manufacturing a semiconductor package in order according to an example embodiment of the present disclosure.

### DETAILED DESCRIPTION

Hereinafter, embodiments of the present disclosure will be described as follows with reference to the accompanying drawings. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

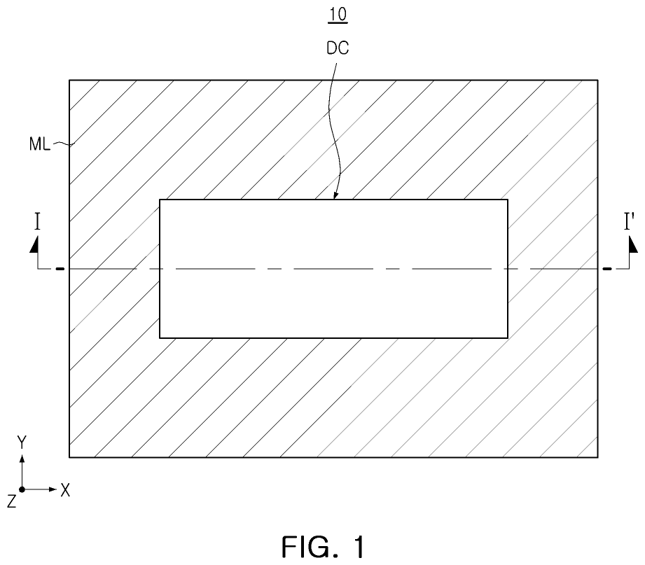

FIG. 1 is a plan diagram illustrating a semiconductor package according to an example embodiment.

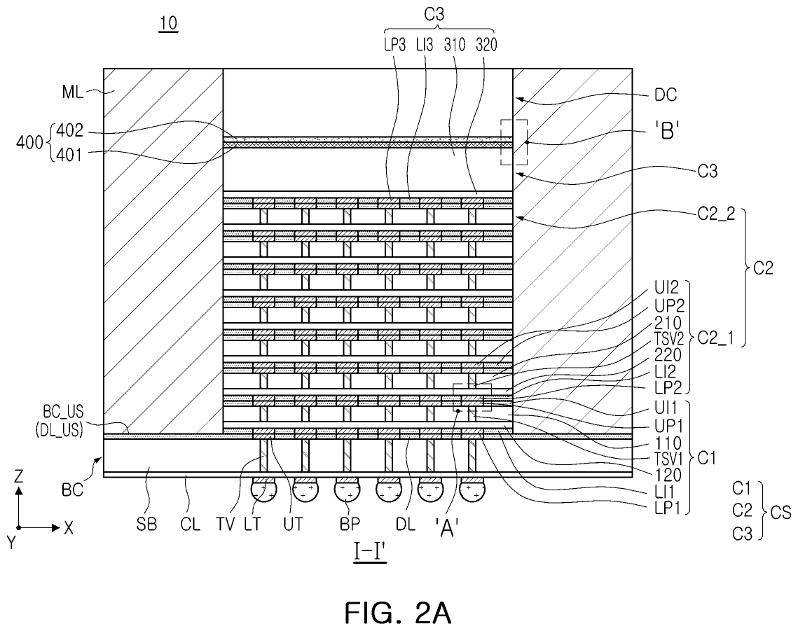

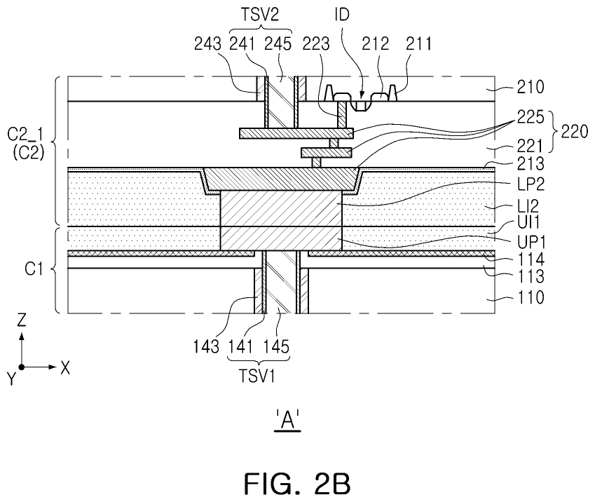

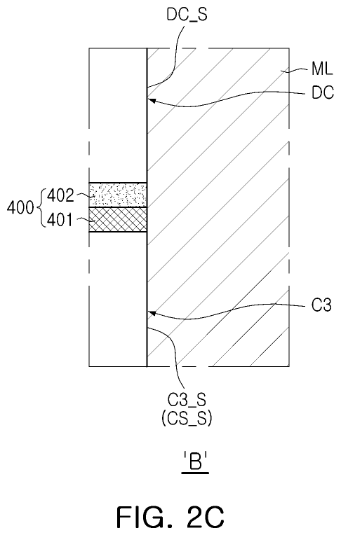

FIG. 2A is a cross-sectional diagram illustrating a semiconductor package taken along line I-I′ in FIG. 1.

FIG. 2B is an enlarged diagram illustrating region ‘A’ illustrated in FIG. 2A.

FIG. 2C is an enlarged diagram illustrating region ‘B’ illustrated in FIG. 2A.

Referring to FIGS. 1 to 2C, a semiconductor package 10 in an example embodiment may include a semiconductor chip stack CS, a dummy chip DC on the semiconductor chip stack CS, and a plurality of adhesive layers 400 between the semiconductor chip stack CS and the dummy chip DC. The semiconductor chip stack CS may include a plurality of semiconductor chips C1, C2, and C3 stacked in order on the base chip BC. In example embodiments, the semiconductor package 10 may further include an encapsulant ML and/or a plurality of connection bumps BP.

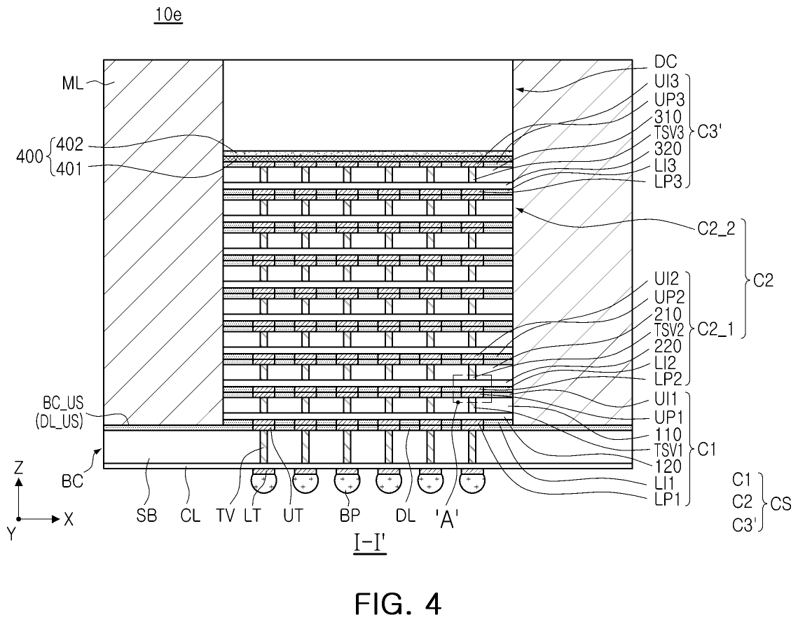

The plurality of semiconductor chips C1, C2, and C3 may be configured as memory chips or memory devices storing or outputting data based on an address command and a control command received from the base chip BC. For example, the plurality of semiconductor chips C1, C2, and C3 may include volatile memory devices such as a DRAM or SRAM, or nonvolatile memory devices such as a PRAM, MRAM, FeRAM, or RRAM. In some example embodiments, among the plurality of semiconductor chips C1, C2, and C3, the third semiconductor chip C3 (hereinafter, the ‘third semiconductor chip’) on an uppermost side may not include a through-electrode, but an example embodiment thereof is not limited thereto. In other example embodiments, among the plurality of semiconductor chips, the semiconductor chip (e.g., semiconductor chip C3′ in FIG. 4) on the uppermost side may include, for example, a through-electrode (see FIG. 4).

The plurality of semiconductor chips C1, C2, and C3 may include a first semiconductor chip C1, at least one second semiconductor chip C2, and a third semiconductor chip C3 stacked in order on the base chip BC in the first direction (e.g., the Z-direction).

The base chip BC may include a substrate SB, lower connection terminals LT and upper connection terminals UT opposite to each other, a device layer CL, and through-vias TV electrically connecting the lower connection terminals LT to the upper connection terminals UT. The base chip BC may further include an upper protective layer DL surrounding the upper connection terminals UT. An upper surface DL_US of the upper protective layer DL may be coplanar with upper surfaces of the upper connection terminals UT.

The base chip BC may be, for example, a buffer chip including a plurality of logic devices and/or memory devices in the device layer CL. Accordingly, the base chip BC may transfer signals from the plurality of semiconductor chips C1, C2, and C3 stacked on the upper portion to an external entity, and may also transfer signals and power from an external entity to the plurality of semiconductor chips C1, C2, and C3. The base chip BC may perform both a logic function and a memory function through the logic devices and the memory devices, but in example embodiments, the base chip BC may include only logic devices and may perform only the logic function.

The substrate SB may include a semiconductor element, such as silicon or germanium (Ge), or a compound semiconductor, such as silicon carbide (SiC), gallium arsenide (GaAs), indium arsenide (InAs), or indium phosphide (InP). The substrate SB may have a silicon on insulator (SOI) structure. The substrate SB may include a conductive region, such as a well doped with impurities, or a structure doped with impurities. The substrate SB may include various device isolation structures, such as a shallow trench isolation (STI) structure.

The upper connection terminals UT may be disposed on an upper surface of the substrate SB (or an upper portion of the base chip BC). The upper connection terminals UT may include a conductive material. The upper connection terminals UT may include, for example, copper (Cu). The lower connection terminals LT may be disposed on a lower surface of the device layer CL (or the lower portion of the base chip BC). The lower connection terminals LT may contact the lower surface of the device layer CL. The lower connection terminals LT may include the same material as the upper connection terminals UT, but an example embodiment thereof is not limited thereto. For example, the lower connection terminals LT may include at least one of aluminum (Al), nickel (Ni), tungsten (W), platinum (Pt) and gold (Au).

The upper protective layer DL may be formed on an upper surface of the substrate SB and may protect the substrate SB. The upper protective layer DL may be formed of an insulating layer such as a silicon oxide film, a silicon nitride film, or a silicon oxynitride film, but the material of the upper protective layer DL is not limited to the above-mentioned materials. For example, the upper protective layer DL may be formed of a polymer such as polyimide (PI) or photosensitive polyimide (PSPI). Although not illustrated in the drawing, a lower protective layer may be formed on the lower surface of the device layer CL.

The device layer CL may be disposed on a lower surface of the substrate SB and may include various types of devices. For example, the device layer CL may include various active devices and/or passive devices such as, for example, field effect transistors (FET) such as planar field effect transistors (FET) or fin-type FETs (FinFET), memory devices such as flash memory, dynamic random access memory (DRAM), static random access memory (SRAM), electrically erasable programmable read-only memory (EEPROM), phase-change random access memory (PRAM), magnetoresistive random access memory (MRAM), ferroelectric random access memory (FeRAM), resistive random access memory (RRAM), logic devices such as AND, OR, and NOT, large scale integration (LSI), CMOS imaging sensor (CIS), and micro-electro-mechanical system (MEMS).

The device layer CL may include an interlayer insulating layer (not illustrated) and a multilayer interconnection layer (not illustrated) on the above-described devices. The interlayer insulating layer (not illustrated) may include silicon oxide or silicon nitride. The multilayer interconnection layer (not illustrated) may include multilayer interconnection and/or vertical contact. The multilayer interconnection layer (not illustrated) may connect devices of the device layer CL to each other, may connect devices to a conductive region of the substrate SB, or may connect devices to lower connection terminals LT.

The through-vias TV may penetrate the substrate SB in a vertical direction (Z-direction) and may provide an electrical path connecting the lower connection terminals LT to the upper connection terminals UT. The through-vias TV may be electrically connected to the plurality of semiconductor chips C1, C2, and C3. The through-vias TV may include a conductive plug and a barrier film surrounding the conductive plug. The conductive plug may include a metal material, for example, tungsten (W), titanium (Ti), aluminum (Al), or copper (Cu). The conductive plug may be formed by a plating process, a PVD process, or a CVD process. The barrier film may include titanium (Ti), titanium nitride (TiN), tantalum (Ta), or tantalum nitride (TaN) and may be formed by a plating process, a PVD process, or a CVD process. A side insulating film (not illustrated) including an insulating material (e.g., high aspect ratio process (HARP) oxide) such as silicon oxide, silicon nitride, or silicon oxynitride may be formed between side surface of the through-via TV and the substrate SB.

Connection bumps BP may be disposed below the base chip BC. For example, connection bumps BP may be provided on and in contact with the lower connection terminals LT. The connection bumps BP may be electrically connected to the plurality of semiconductor chips C1, C2, and C3 through through-vias TV. The connection bumps BP may include, for example, tin (Sn) or an alloy including tin (Sn) (e.g., Sn—Ag—Cu). Accordingly, the connection bumps BP may include a combination of a metal pillar and a solder ball. The connection bumps BP may be electrically connected to an external device such as a module substrate, a system board, or the like. The base chip BC may have a width in the horizontal direction (e.g., X- and/or Y-direction) greater than each of widths of the plurality of semiconductor chips C1, C2, and C3. Although not illustrated, at least a portion of the connection bumps BP and at least a portion of the lower connection terminals LT may be disposed in positions not overlapping the plurality of semiconductor chips C1, C2, and C3 in the vertical direction (Z-direction).

The first semiconductor chip C1 may be disposed on the base chip BC and may include a first substrate 110, a first circuit layer 120, first lower pads LP1 and first upper pads UP1 opposite to each other, and first through-electrodes TSV1 electrically connecting the first lower pads LP1 to the first upper pads UP1. In example embodiments, the first semiconductor chip C1 may further include a first lower insulating layer LI1 surrounding the first lower pads LP1 and a first upper insulating layer UI1 surrounding the first upper pads UP1.

The first substrate 110 may include a semiconductor element, such as silicon or germanium (Ge), or a compound semiconductor, such as silicon carbide (SiC), gallium arsenide (GaAs), indium arsenide (InAs), or indium phosphide (InP). The first substrate 110 may have a silicon on insulator (SOI) structure. The first substrate 110 may include a conductive region, such as a well doped with impurities, or a structure doped with impurities. The first substrate 110 may include various device isolation structures, such as a shallow trench isolation (STI) structure. In an example embodiment, the first substrate 110 may be referred to as a first semiconductor substrate.

The first upper pads UP1 may be disposed on an upper surface of the first substrate 110 (or an upper portion of the first semiconductor chip C1). The first upper pads UP1 may be formed of or include a conductive material. The first upper pads UP1 may be formed of or include, for example, copper (Cu). The first lower pads LP1 may be disposed on a lower surface of the first lower insulating layer LI1 (or a lower portion of the first semiconductor chip C1). The first lower pads LP1 may be formed of or include a conductive material. The first lower pads LP1 may be formed of or include a material the same as or similar to that of the first upper pads UP1.

The first upper insulating layer UI1 may be formed on the upper surface of the first substrate 110 and may protect the first substrate 110. The first upper insulating layer UI1 may surround side surfaces of the first upper pads UP1. The first upper insulating layer UI1 may contact the side surfaces of the first upper pads UP1. The first upper insulating layer UI1 may be formed of an insulating layer such as a silicon oxide film, a silicon nitride film, a silicon oxynitride film, or the like, but the material of the first upper insulating layer UI1 is not limited to the above-mentioned materials. For example, the first upper insulating layer UI1 may be formed of a polymer such as polyimide (PI) or photosensitive polyimide (PSPI).

The first lower insulating layer LI1 may be formed on a lower surface of the first substrate 110 and may protect the first circuit layer 120. The first lower insulating layer LI1 may surround side surfaces of the first lower pads LP1. The first lower insulating layer LI1 may contact the side surfaces of the first lower pads LP1. The first lower insulating layer LI1 may include, for example, silicon oxide (SiO) or silicon carbon nitride (SiCN).

The first circuit layer 120 may be formed between the first substrate 110 and the first lower insulating layer LI1. The first circuit layer 120 may be substantially the same as or similar to the second circuit layer 220 described with reference to FIG. 2B.

The first through-electrodes TSV1 may penetrate the first substrate 110 in the vertical direction (Z-direction) and may provide an electrical path connecting the first lower pads LP1 to the first upper pads UP1. The first through-electrodes TSV1 may include a via plug 145 and a side barrier layer 141 surrounding a side surface thereof. Upper and lower surfaces of the via plug 145 may be coplanar with upper and lower surfaces of side barrier layer 141, respectively. The via plug 145 may include, for example, tungsten (W), titanium (Ti), aluminum (Al), or copper (Cu), and may be formed by a plating process, a PVD process, or a CVD process. The side barrier layer 141 may include, for example, titanium (Ti), titanium nitride (TiN), tantalum (Ta), or tantalum nitride (TaN), and may be formed by a plating process, a PVD process, or a CVD process. A side insulating film 143 including an insulating material (e.g., HARP oxide) such as silicon oxide, silicon nitride, or silicon oxynitride may be formed between the side barrier layer 141 and the first substrate 110. The side insulating film 143 may contact a side surface of the side barrier layer 141.

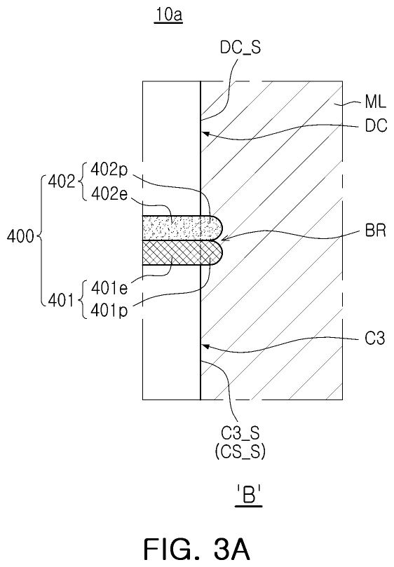

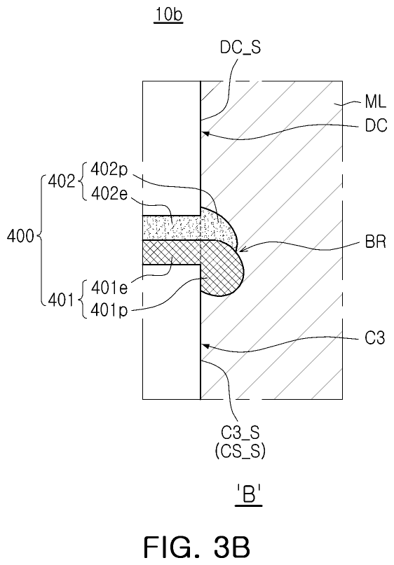

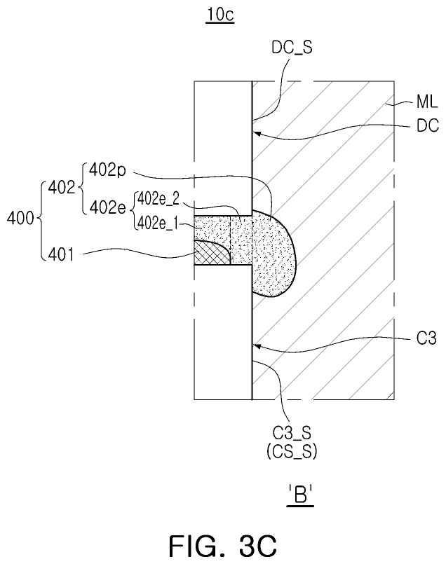

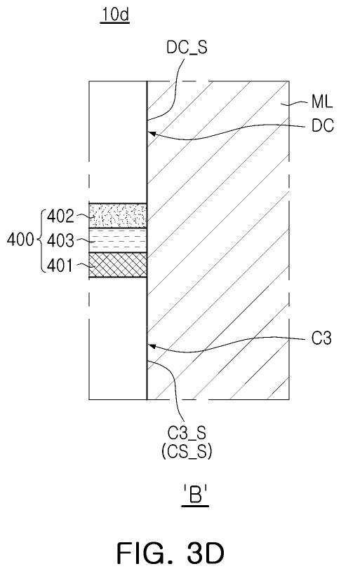

The first through-electrodes TSV1 may penetrate an insulating protective layer 113 formed on a back surface of the first substrate 110. The insulating protective layer 113 may contact side surfaces of the first through-electrodes TSV1. The insulating protective layer 113 may include, for example, silicon oxide (SiO), silicon nitride (SiN), silicon carbide (SiC), silicon oxynitride (SiON), or silicon carbonitride (SiCN). A buffer film 114, such as a polishing stop layer or barrier, may be disposed on the insulating protective layer 113. The buffer film 114 may contact upper and side surfaces of the insulating protective layer 113. The buffer film 114 and the insulating protective layer 113 may contact lower surfaces of the first upper pads UP1. Uppermost surfaces of the insulating protective layer 113, the buffer film 114, and the first through-electrodes TSV1 may be coplanar. Uppermost surfaces of the buffer film 114 and the insulating protective layer 113 may contact lower surfaces of the first upper pads UP1. For example, the buffer film may include silicon nitride, silicon carbide, silicon oxynitride, or silicon carbonitride (see FIG. 3).

The first semiconductor chip C1 and the base chip BC may be bonded and coupled to each other by metal-to-metal bonding and dielectric-to-dielectric bonding.

For example, the first lower pads LP1 of the first semiconductor chip C1 and the upper connection terminals UT of the base chip BC may be in contact with each other. The first lower insulating layer LI1 of the first semiconductor chip C1 and the upper protective layer DL of the base chip BC may be in contact with each other.

At least one second semiconductor chip C2 may be disposed on the first semiconductor chip C1. At least one second semiconductor chip C2 may include a plurality of second semiconductor chips stacked in order on the first semiconductor chip C1 in the first direction (e.g., Z-direction). The plurality of second semiconductor chips C2 may include a lowermost second semiconductor chip (hereinafter, a second-first semiconductor chip C2_1) and an uppermost side second semiconductor chip (hereinafter, a second-second semiconductor chip C2_2).

Each of the plurality of second semiconductor chips C2 may include a second substrate 210, a second circuit layer 220, second lower pads LP2 and second upper pads UP2 opposite to each other, and second through-electrodes TSV2 electrically connecting the second lower pads LP2 to the second upper pads UP2. In example embodiments, each of the plurality of second semiconductor chips C2 may further include a second lower insulating layer UI2 surrounding the second lower pads LP2 and a second upper insulating layer UI2 surrounding the second upper pads UP2. In example embodiments, each of the plurality of second semiconductor chips C2 may further include an insulating liner 213.

The second substrate 210 may be substantially the same as the first substrate 110. In an example embodiment, the second substrate 210 may be referred to as a second semiconductor substrate.

The second upper pads UP2 may be disposed on an upper surface of the second substrate 210 (or an upper portion of each of a plurality of second semiconductor chips C2). The second upper pads UP2 may be formed of or include a conductive material. The second upper pads UP2 may be formed of or include, for example, copper (Cu). The second lower pads LP2 may be disposed on a lower surface of the second lower insulating layer LI2 (or a lower portion of each of a plurality of second semiconductor chips C2). The second lower pads LP2 may be formed of or include a conductive material. The second lower pads LP2 may be formed of or include a material the same as or similar to that of the second upper pads UP2.

The second upper insulating layer UI2 may be formed on an upper surface of the second substrate 210 and may protect the second substrate 210. The second upper insulating layer UI2 may surround side surfaces of the second upper pads UP2. The second upper insulating layer UI2 may contact side surfaces of the second upper pads UP2. The second upper insulating layer UI2 may be formed of an insulating layer such as a silicon oxide film, a silicon nitride film, or a silicon oxynitride film, but the material of the second upper insulating layer UI2 is not limited to the above-mentioned materials. For example, the second upper insulating layer UI2 may be formed of a polymer such as polyimide (PI) or photosensitive polyimide (PSPI).

The insulating liner 213 and the second lower insulating layer LI2 may be formed on a lower portion of the second substrate 210 and may protect the second circuit layer 220. The second lower insulating layer LI2 may surround side surfaces of the second lower pads LP2. The insulating liner 213 may be disposed on the lower surface of the second substrate 210, surround the side surface of the lowermost interconnection structure among the interconnection structures 225, and cover a portion of the lower surface of the lowermost wiring structure. The insulating liner 213 may be in contact with the side surface of the second lower pads LP2. The insulating liner 213 may include an insulating material such as silicon oxide, silicon nitride, or silicon oxynitride. The second lower insulating layer LI2 may contact the side surfaces of the second lower pads LP2. The second lower insulating layer LI2 may include, for example, silicon oxide (SiO) or silicon carbon nitride (SiCN).

The second circuit layer 220 may be disposed on a front surface of the second substrate 210 on which the conductive region 212 is formed. The second circuit layer 220 may include individual devices ID, an interlayer insulating layer 221, and an interconnection structure 225. The conductive region 212 may be, for example, a well doped with impurities or a structure doped with impurities. The second substrate 210 may further include an isolation region 211. The isolation region 211 includes a device isolation structure having a shallow trench isolation (STI) structure and may include silicon oxide

The individual devices ID may be disposed on a front surface of the second substrate 210. The individual devices ID may include various active devices and/or passive devices, such as, for example, FETs such as planar FETs or FinFETs, memory devices such as flash memory, DRAM, SRAM, EEPROM, PRAM, MRAM, FeRAM, RRAM, logic devices such as AND, OR, NOT, system LSI, CIS, MEMS, or the like.

The interlayer insulating layer 221 may be formed to cover the individual devices ID and interconnection structure 225, and may electrically isolate the individual devices ID disposed on the second substrate 210 from each other. The interlayer insulating layer 221 may be formed of or include flowable oxide (FOX), tonen silazen (TOSZ), undoped silica glass (USG), borosilica glass (BSG), phosphosilaca glass (PSG), borophosphosilica glass (BPSG), plasma enhanced tetra ethyl ortho silicate (PETEOS), fluoride silicate glass (FSG), high density plasma (HDP) oxide, plasma enhanced oxide (PEOX), flowable CVD (FCVD) oxide or combinations thereof. At least a partial region of the interlayer insulating layer 221 surrounding the interconnection structure 225 may be formed of a low-κ dielectric layer. The interlayer insulating layer 221 may be formed using chemical vapor deposition (CVD), a flowable-CVD process, or a spin coating process. According to the process, a boundary between the interlayer insulating layer 221 and the second lower insulating layer LI2 may not be distinct.

The interconnection structure 225 may be formed as a multilayer structure including a plurality of interconnection patterns and a plurality of vias, for example, formed of aluminum (Al), gold (Au), cobalt (Co), copper (Cu), nickel (Ni), lead (Pb), tantalum (Ta), tellurium (Te), titanium (Ti), tungsten (W), or a combination thereof. A barrier film (not illustrated) including titanium (Ti), titanium nitride (TiN), tantalum (Ta), or tantalum nitride (TaN) may be disposed between the interconnection patterns or/and vias and the interlayer insulating layer 221. The interconnection structure 225 may be electrically connected to the conductive region 212 and/or individual devices ID by an interconnection portion 223 (e.g., a contact plug).

The second through-electrodes TSV2 may penetrate the second substrate 210 in the vertical direction (Z-direction) and may provide an electrical path connecting the second lower pads LP2 to the second upper pads UP2. The second through-electrodes TSV2 may include a via plug 245 and a side barrier layer 241 surrounding a side surface thereof. Upper and lower surfaces of the via plug 245 may be coplanar with upper and lower surfaces of the side barrier layer 241, respectively. The via plug 245 may include, for example, tungsten (W), titanium (Ti), aluminum (Al), or copper (Cu), and may be formed by a plating process, a PVD process, or a CVD process. The side barrier layer 241 may include titanium (Ti), titanium nitride (TiN), tantalum (Ta), or tantalum nitride (TaN), and may be formed by a plating process, a PVD process, or a CVD process. Between the side barrier layer 241 and the second substrate 210, a side insulating film 243 including an insulating material such as silicon oxide, silicon nitride, or silicon oxynitride (e.g., HARP oxide) may be formed. The side insulating film 243 may contact side surfaces of the side barrier layer 241 and an upper surface of the interlayer insulating layer 221.

The lowermost second-first semiconductor chip C2_1 and the first semiconductor chip C1 may be bonded and coupled to each other by metal-to-metal bonding and dielectric-to-dielectric bonding.

For example, the second lower pads LP2 of the second-first semiconductor chip C2_1 and the first upper pads UP1 of the first semiconductor chip C1 may be in contact with each other, respectively. The second lower insulating layer LI2 of the second-first semiconductor chip C2_1 and the first upper insulating layer UI1 of the first semiconductor chip C1 may be in contact with each other, respectively.

Second semiconductor chips adjacent to each other in the first direction (e.g., Z-direction) among the plurality of second semiconductor chips C2 may be bonded and coupled to each other by metal-to-metal bonding and dielectric-to-dielectric bonding. Second upper pads UP2 of each of the plurality of second semiconductor chips C2 may be in contact with second lower pads LP2 of each of the plurality of second semiconductor chips C2 adjacent to each other in the first direction, respectively. The second insulating layers LI2 and UI2 of each of the plurality of second semiconductor chips C2 may be in contact with the second insulating layers LI2 and UI2 of each of the plurality of second semiconductor chips C2 adjacent to each other in the first direction, respectively.

The third semiconductor chip C3 may be disposed on the second-second semiconductor chip C2_2, and may include a third substrate 310, a third circuit layer 320, a third lower insulating layer LI3, and front surface pads LP3 disposed on the front surface. The third substrate 301, the third circuit layer 320 and the front surface pads LP3 may be configured the same as or similar to the corresponding components of the base chip BC, the first substrate 110, the first circuit layer CL and the lower connection terminals LT described above, such that overlapping description thereof will not be provided.

The front surface pads LP3 of the third semiconductor chip 300 may be in contact with the second lower pads LP2 of the second-second semiconductor chip C2 adjacent to each other in the first direction, respectively. The third lower insulating layer LI3 of the third semiconductor chip 300 may be in contact with the second upper insulating layers LI2 of the second-second semiconductor chip C2 adjacent to each other in the first direction.

The dummy chip DC may be disposed on the third semiconductor chip C3. The dummy chip DC may be a dummy component disposed on the semiconductor chip stack CS when a height of the semiconductor chip stack CS is smaller than a height of the intended semiconductor package. From a different perspective, the dummy chip DC may be electrically isolated from the semiconductor chip stack CS.

A side surface DC_S of the dummy chip DC may be aligned with a side surface CS_S of the semiconductor chip stack CS. For example, the side surface DC_S of the dummy chip DC may be aligned with a side surface C3_S of the third semiconductor chip C3. From a different perspective, a width of the dummy chip DC in the horizontal direction (e.g., X and/or Y-direction) may be substantially the same as a width of each of the plurality of semiconductor chips C1, C2, and C3 in the horizontal direction. A back surface of the dummy chip DC may be exposed rather than being covered by the encapsulant ML. The back surface of the dummy chip DC may be substantially coplanar with an upper surface of the encapsulant ML. The back surface of the dummy chip DC may also be referred to as the upper surface of the dummy chip DC.

A plurality of adhesive layers 400 may be disposed between the semiconductor chip stack CS and the dummy chip DC. From a different perspective, the dummy chip DC may be fixed by the plurality of adhesive layers 400 rather than being in direct contact with the uppermost side semiconductor chip (e.g., the third semiconductor C3).

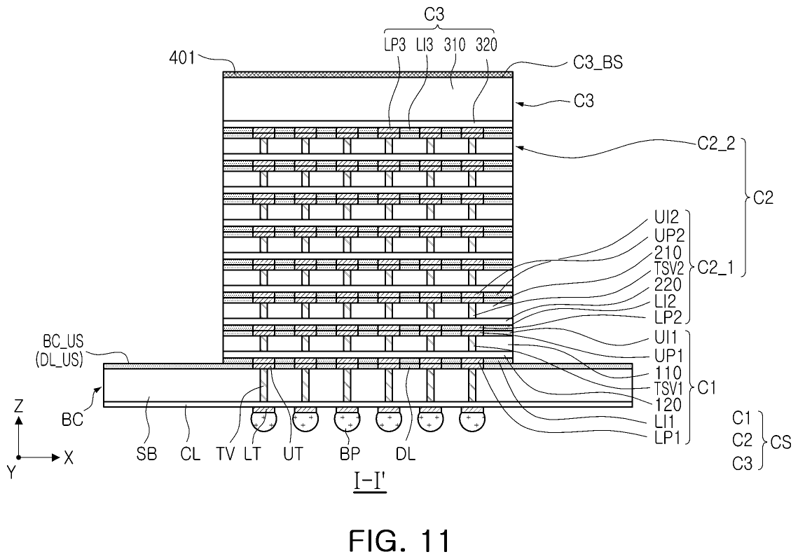

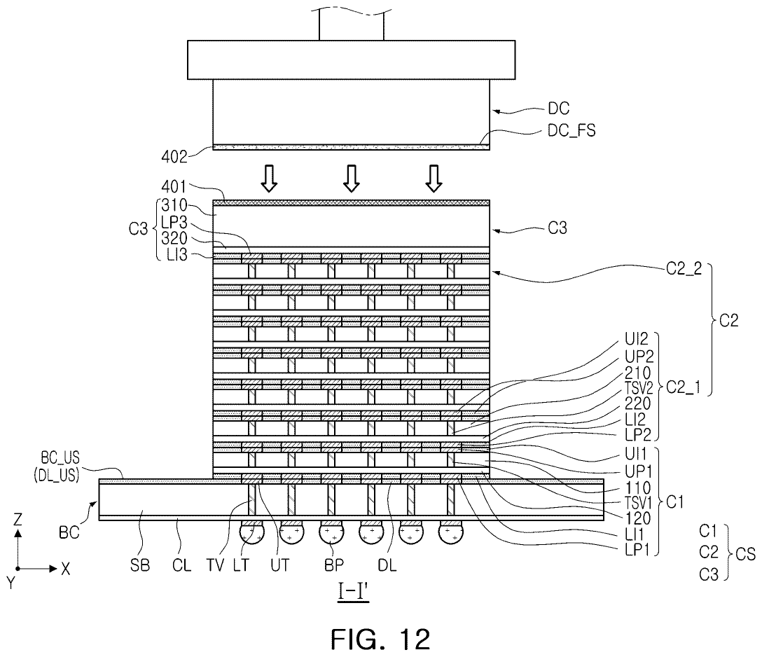

A plurality of adhesive layers 400 may include first and second adhesive layers 401 and 402. The first adhesive layer 401 may be provided by being adhered to the back surface (“C3_BS” in FIG. 11) of the third semiconductor chip C3. The second adhesive layer 402 may be provided by being adhered to the front surface (“DC_FS” in FIG. 12) of the dummy chip DC. In an example embodiment, each of the plurality of adhesive layers 400 may be a NCF (Non-Conductive Film), but an example embodiment thereof is not limited thereto. The plurality of adhesive layers 400 may include various types of polymer films on which a thermal compression process may be performed.

Side surfaces of the first and second adhesive layers 401 and 402 may be aligned with side surfaces of the semiconductor chip stack CS and the dummy chip DC, respectively. For example, the side surface of the first adhesive layer 401 may be aligned with the side surface C3_S of the third semiconductor chip C3 (or the side surface CS_S of the semiconductor chip stack CS), and the side surface of the second adhesive layer 402 may be aligned with the side surface of the dummy chip DC. From a different perspective, the first and second adhesive layers 401 and 402 may have the same width in the horizontal direction (e.g., X and/or Y-direction). Also, from a different perspective, the first and second adhesive layers 401 and 402 may not include a protrusion (or fillet portion) extending into the encapsulant ML. The encapsulant ML may contact side surface of the first and second adhesive layers 401 and 402.

By disposing the plurality of adhesive layers 400 between the semiconductor chip stack CS and the dummy chip DC, debris detaching from the plurality of adhesive layers 400 may be reduced or prevented. The debris may refer to impurities (e.g., fumes) caused by a predetermined heat pressing process for strengthening adhesion of the plurality of adhesive layers 400.

For example, as compared to directly disposing the adhesive layer formed on the front surface of the dummy chip DC on the back surface of the third semiconductor chip C3, by disposing the second adhesive layer 402 formed on the front surface of the dummy chip DC on the first adhesive layer 401 formed on the back surface of the third semiconductor chip C3, adhesive strength of the first and second adhesive layers 401 and 402 may be sufficiently activated even by a thermal compression process under relatively low pressure and low temperature conditions.

Accordingly, unnecessary formation of debris on the upper surface BC_US of the base chip BC may be reduced or prevented, and accordingly, deterioration of the cohesion force between the base chip BC and the encapsulant ML may be reduced or prevented.

The encapsulant ML may encapsulate the semiconductor chip stack CS on the base chip BC. The encapsulant ML may be formed to expose the back surface of the dummy chip DC. According to another example embodiment, the encapsulant ML may be formed to cover the back surface of the dummy chip DC. The encapsulant ML may be formed of an insulating material, such as an epoxy mold compound (EMC), but the material of the encapsulant ML is not limited to any particular example. The encapsulant ML may surround side surfaces CS_S of the plurality of semiconductor chips C1, C2, and C3, side surfaces of the plurality of adhesive layers 400, and side surface DC_S of the dummy chip DC. According to the example embodiment, a heat dissipation structure (not illustrated) may be disposed in an upper portion of the encapsulant ML. The heat dissipation structure (not illustrated) may control warpage of the semiconductor package 10 and may dissipate heat generated in the plurality of semiconductor chips C1, C2, and C3 to an external entity.

FIGS. 3A to 3D are enlarged diagrams illustrating a portion of a semiconductor package according to modified examples of the present disclosure, illustrating region ‘B’ in FIG. 2A.

Referring to FIGS. 3A to 3C, the example embodiments may be substantially the same as the example described with reference to FIGS. 1 to 2C, other than the configuration in which at least one a portion of the plurality of adhesive layers 400 may extend into the encapsulant ML. For example, in the embodiments of FIGS. 3A to 3C, widths in the horizontal direction (e.g., X and/or Y-direction) of the plurality of adhesive layers 400 may be wider than a width of the dummy chip DC the horizontal direction and widths of each of the plurality of semiconductor chips C1, C2, and C3 in the horizontal direction.

Referring to FIG. 3A, the semiconductor package 10a may be substantially the same as the example described with reference to FIGS. 1 to 2C, other than the configuration in which the semiconductor package 10a includes first and second adhesive layers 401 and 402 having first and second protrusions 401p and 402p, respectively. For example, widths in the horizontal direction (e.g., X and/or Y-direction) of the first and second adhesive layers 401 and 402 may be wider than a width of the dummy chip DC in the horizontal direction and widths of each of the plurality of semiconductor chips C1, C2, and C3 in the horizontal direction.

The first adhesive layer 401 may include a first extension portion 401e extending on the back surface of the third semiconductor chip C3, and a first protrusion 401p protruding further than the side surface C3_S of the third semiconductor chip C3. The first protrusion 401p may be a fillet portion connected to the first extension portion 401e and extending into the encapsulant ML. In this case, the first protrusion 401p may be referred to as a first fillet portion.

The second adhesive layer 402 may include a second extension portion 402e extending on the front surface of the dummy chip DC, and a second protrusion 402p protruding further than the side surface DC_S of the dummy chip DC. The second protrusion 402p may be a fillet portion connected to the second extension portion 402e and extending into the encapsulant ML. In this case, the second protrusion 402p may be referred to as a second fillet portion.

An upper surface of the first extension portion 401e and a lower surface of the second extension portion 402e may be in contact with each other. A boundary region BR may be defined between the first protrusion 401p and the second protrusion 402p. The boundary region BR may be a concave region between ends of the first and second protrusions 401p and 402p. From a different perspective, the boundary region BR may be a groove or a recessed portion between the ends.

Referring to FIG. 3B, a semiconductor package 10b may be substantially the same as the examples described with reference to FIGS. 1 to 3A, other than the configuration in which the semiconductor package 10b includes first and second adhesive layers 401 and 402 having first and second protrusions 401p and 402p, respectively. For example, widths in the horizontal direction (e.g., X and/or Y-direction) of the first and second adhesive layers 401 and 402 may be wider than a width of the dummy chip DC in the horizontal direction and widths of each of the plurality of semiconductor chips C1, C2, and C3 in the horizontal direction.

The first adhesive layer 401 may include a first extension portion 401e extending on the back surface of the third semiconductor chip C3, and a first protrusion 401p protruding further than the side surface C3_S of the third semiconductor chip C3. The first protrusion 401p may be a fillet portion connected to the first extension portion 401e and extending into the encapsulant ML. In this case, the first protrusion 401p may be referred to as a first fillet portion.

The second adhesive layer 402 may include a second extension portion 402e extending on the front surface of the dummy chip DC, and a second protrusion 402p protruding further than the side surface DC_S of the dummy chip DC. The second protrusion 402p may be a fillet portion connected to the second extension portion 402e and extending into the encapsulant ML. In this case, the second protrusion 402p may be referred to as a second fillet portion.

The upper surface of the first extension portion 401e and the lower surface of the second extension portion 402e may be in contact with each other.

A boundary region BR may be defined between the first protrusion 401p and the second protrusion 402p. The boundary region BR may be a concave region between ends of the first and second protrusions 401p and 402p. From a different perspective, the boundary region BR may be a step difference between the ends.

In the example embodiment, at least a portion of the first protrusion 401p may extend toward the upper surface of the base chip BC (BC_US in FIG. 2A) and may be in contact with the side surface C3_S of the third semiconductor chip C3. At least a portion of the second protrusion 402p may extend in a direction away from the upper surface of the base chip BC (BC_US in FIG. 2A) (e.g., in the Z-direction) and may be in contact with the side surface DC_S of the dummy chip DC. An area in which the first protrusion 401p is in contact with the side surface C3_S may be greater than an area in which the second protrusion 402p is in contact with the side surface DC_S. The upper portion of the first protrusion 401p and the lower portion of the second protrusion 402p may be in contact with each other.

In the example embodiment, a maximum width of the first protrusion 401p in the horizontal direction (e.g., X and/or Y-direction) may be greater than a maximum width in the horizontal direction of the second protrusion 402p.

Referring to FIG. 3C, the semiconductor package 10c may be substantially the same as the examples described with reference to FIGS. 1 to 3B, other than the configuration in which the first adhesive layer 401 having a width smaller than the width of the third semiconductor chip C3 is included. For example, a width in the horizontal direction (e.g., X and/or Y-direction) of the second adhesive layer 402 may be wider than a width of the dummy chip DC the horizontal direction and widths of each of the plurality of semiconductor chips C1, C2, and C3 in the horizontal direction, and a width in the horizontal direction (e.g., X and/or Y-direction) of the first adhesive layer 401 may be smaller than a width of the dummy chip DC in the horizontal direction and widths of each of the plurality of semiconductor chips C1, C2, and C3 in the horizontal direction.

The first adhesive layer 401 may extend on the back surface of the third semiconductor chip C3 and may have a width smaller than a width of the third semiconductor chip C3. An end of the first adhesive layer 401 may have a rounded shape. For example, a thickness in the vertical direction (e.g., Z-direction) of the first adhesive layer 401 may decrease toward the end. In the example embodiment, the first adhesive layer 401 may be referred to as a first portion.

The second adhesive layer 402 may include a second extension portion 402e extending on the front surface of the dummy chip DC, and a second protrusion 402p protruding further than the side surface C3_S of the third semiconductor chip C3 and the side surface DC_S of the dummy chip DC.

The second extension portion 402e may include a second-first portion 402e_1 covering an upper portion of the first adhesive layer 401, and a second-second portion 402e_2 connected to the second-first portion 402e_1 and covering a side portion of the first adhesive layer 401. The second-second portion 402e_2 may contact the side portion of the first adhesive layer 401.

The second protrusion 402p may be a fillet portion connected to the second-second portion 402e_2 and extending into the encapsulant ML. The second protrusion 402p may be in contact with the side surface C3_S of the third semiconductor chip C3 and the side surface DC_S of the dummy chip DC.

In example embodiments, a plurality of adhesive layers 400 may be disposed between the semiconductor chip stack CS and the dummy chip DC, thereby forming a protrusion (e.g., protrusions 401p and 402p) having a relatively small size, as compared to the example in which a single adhesive layer is disposed. Here, the size may indicate a width, a thickness, and/or a volume of the protrusion. Accordingly, unnecessary formation of debris detached from the adhesive layers on the upper surface BC_US of the base chip BC may be reduced or prevented, and accordingly, a decrease in cohesion force between the base chip BC and the encapsulant ML may be reduced or prevented.

Referring to FIG. 3D, a semiconductor package 10d may be substantially the same as the examples described with reference to FIGS. 1 to 3C, other than the configuration in which a plurality of adhesive layers 400 further includes a third adhesive layer 403 between the first and second adhesive layers 401 and 402.

The third adhesive layer 403 may be provided adhered to the back surface of the third semiconductor chip C3 together with the first adhesive layer 401, but an example embodiment thereof is not limited thereto. For example, the third adhesive layer 403 may be adhered to the front surface of the dummy chip DC together with the second adhesive layer 402.

FIG. 4 is a cross-sectional diagram taken along line I-I′ in FIG. 1.

Referring to FIG. 4, the example embodiment may be substantially the same as the examples described with reference to FIGS. 1 to 3D, other than the configuration in which a third semiconductor chip C3′ of a semiconductor package 10e includes a third through-electrode TSV3.

The third semiconductor chip C3′ may be disposed on an uppermost side of the second semiconductor chip C2_2, and may include a third substrate 310, a third circuit layer 320, third lower pads LP3 and third upper pads UP3, and third through-electrodes TSV3 electrically connecting the third lower pads LP3 to the third upper pads UP3. The third semiconductor chip C3′ may further include a third lower insulating layer LI3 surrounding the third lower pads LP3 and a third upper insulating layer UI3 surrounding the third upper pads UP3. The third substrate 310, the third circuit layer 320, the third lower and upper pads LP3 and UP3, the third through-electrodes TSV3 and the third lower and upper insulating layer LI3 and UI3 in the example embodiment may be substantially the same as the second substrate 210, the second circuit layer 220, the second lower and upper pads LP2 and UP2, the second through-electrodes TSV2 and the second lower and upper insulating layer LI2 and UI2 of the second-second semiconductor chip C2_1 described with reference to FIG. 2A. Accordingly, detailed descriptions thereof will not be repeated.

The third semiconductor chip C3′ and the second-second semiconductor chip C2_2 on the uppermost side may be bonded and coupled to each other by metal-to-metal bonding and dielectric-to-dielectric bonding.

For example, the third lower pads LP3 of the third semiconductor chip C3′ and the third upper pads UP3 of the second-second semiconductor chip C2_2 may be in contact with each other. The third lower insulating layer LI3 of the third semiconductor chip C3′ and the second upper insulating layers LI2 and UI2 of the second-second semiconductor chip C2_2 may be in contact with each other.

In the example embodiment, the first adhesive layer 401 may cover the third upper pads UP3 and the third upper insulating layer UI3.

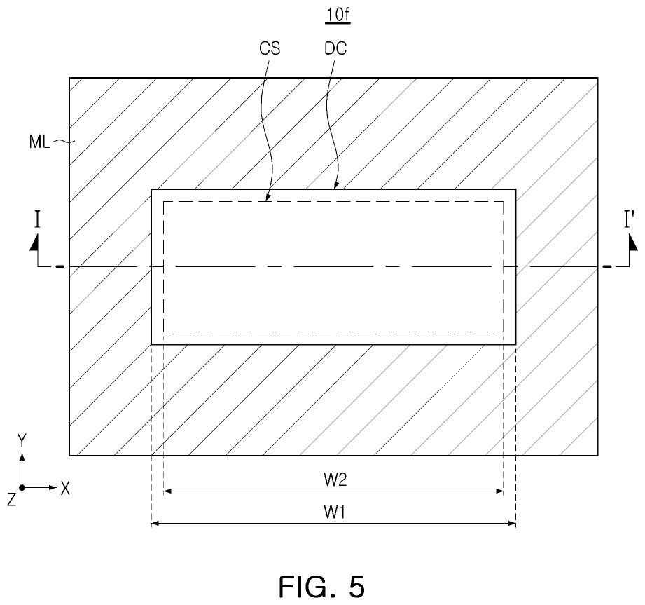

FIG. 5 is a plan diagram illustrating a semiconductor package according to an example embodiment.

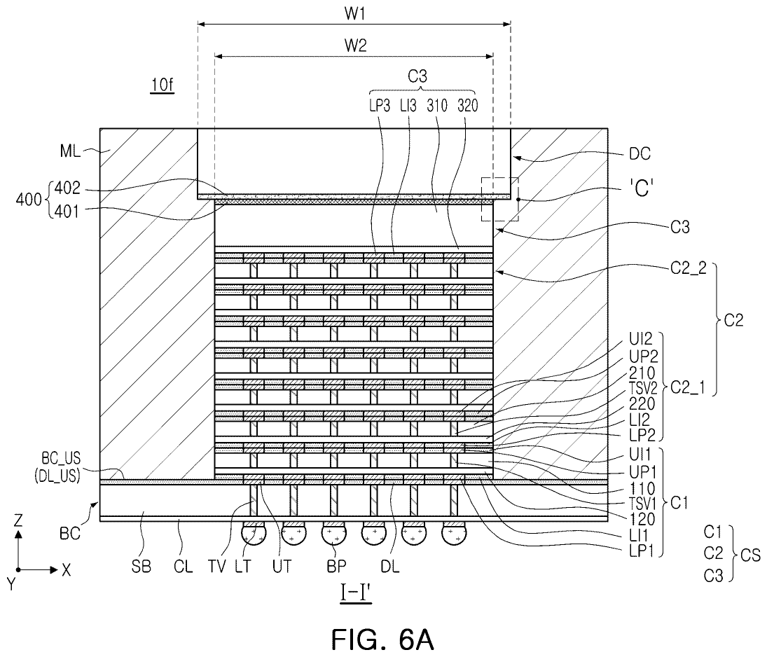

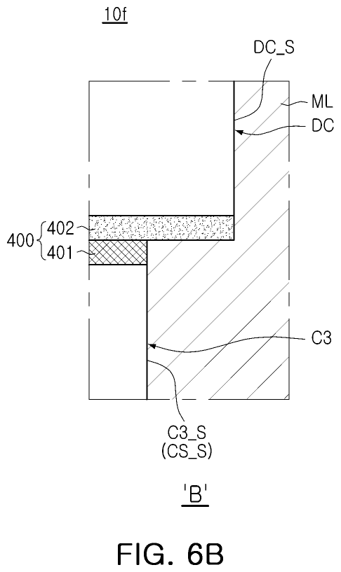

FIG. 6A is a cross-sectional diagram illustrating a semiconductor package taken along line I-I′ in FIG. 5.

FIG. 6B is an enlarged diagram illustrating region ‘C’ in FIG. 6A.

Referring to FIGS. 5 to 6B, the example embodiment may be substantially the same as the examples described with reference to FIGS. 1 to 4, other than the configuration in which a width W1 of the dummy chip DC in the horizontal direction (e.g., X and/or Y-direction) of the semiconductor package 10f is greater than a width W2 of the semiconductor chip stack CS in the horizontal direction. From a different perspective, differently from the semiconductor package 10 described with reference to FIGS. 1 to 2C, in the semiconductor package 10f, the side surface DC_S of the dummy chip DC may not be aligned with the side surface C3_S of the third semiconductor chip C3.

The width W1 in the horizontal direction of the dummy chip DC may be greater than the width W2 in the horizontal direction of the semiconductor chip stack CS (or the width of the third semiconductor chip C3). From a different perspective, the width in the horizontal direction of the second adhesive layer 402 may be greater than the width in the horizontal direction of the first adhesive layer 401. For example, the width in the horizontal direction of the second adhesive layer 402 may be the width W1, and the width in the horizontal direction of the first adhesive layer 401 may be the width W2. Accordingly, the encapsulant ML may cover at least a portion of the lower surface of the first adhesive layer 401. For example, the encapsulant ML may contact the lower surface of the first adhesive layer 401.

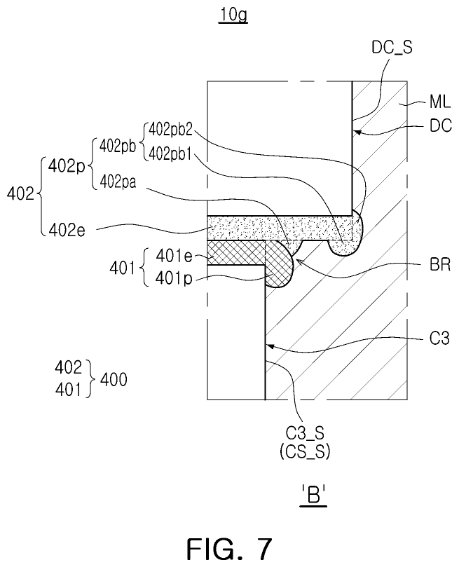

FIG. 7 is an enlarged diagram illustrating a semiconductor package according to a modified example of the present disclosure, illustrating region ‘C’ in FIG. 6A.

Referring to FIG. 7, a semiconductor package 10g may be substantially the same as the examples described with reference to FIGS. 1 to 6B, other than the configuration in which first and second adhesive layers 401 and 402 having first and second protrusions 401p and 402p, respectively, are included.

The first adhesive layer 401 may include a first extension portion 401e extending on the back surface of the third semiconductor chip C3, and a first protrusion 401p protruding further than the side surface C3_S of the third semiconductor chip C3. The first protrusion 401p may be a fillet portion connected to the first extension portion 401e and extending into the encapsulant ML. In this case, the first protrusion 401p may be referred to as the first fillet portion.

The second adhesive layer 402 may include a second extension portion 402e extending on the front surface of the dummy chip DC, and a second protrusion 402p protruding from the second extension portion 402e.

The second protrusion 402p may include a second-first protrusion 402pa protruding from the lower surface of the second extension portion 402e and in contact with the first protrusion 401p. Accordingly, a boundary region BR may be defined between the first protrusion 401p and the second-first protrusion 402pa.

The second protrusion 402p may further include a second-second protrusion 402pb extending from the end of the second extension portion 402e into the encapsulant ML. The second-second protrusion 402pb may be defined as including a first portion 402pb1 protruding from a lower surface of the end of the second extension portion 402e toward an upper surface (e.g., upper surface BC_US in FIG. 6A) of the base chip BC, and a second portion 402bp2 protruding from a side surface of the end of the second extension portion 402e and in contact with a side surface DC_S of the dummy chip DC. The second-second protrusion 402pb of the second protrusion 402p may be referred to as a second fillet portion.

Although not illustrated, the second protrusion 402p may include a plurality of protrusions other than the second-first and second-second protrusions 402pa and 402pb.

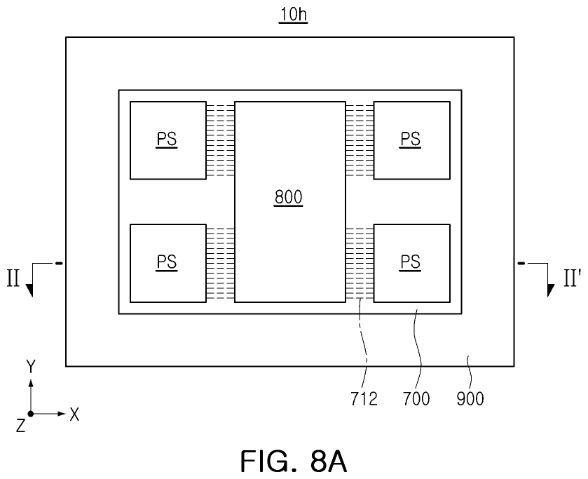

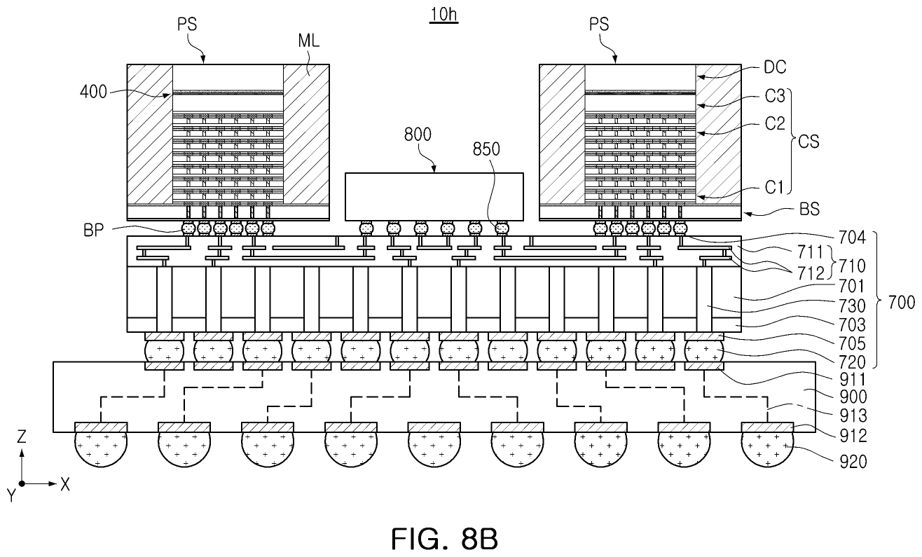

FIG. 8A is a plan diagram illustrating a semiconductor package according to an example embodiment.

FIG. 8B is a cross-sectional diagram illustrating a semiconductor package taken along line II-II′ in FIG. 8A.

Referring to FIGS. 8A and 8B, a semiconductor package 10h may include a package substrate 900, an interposer substrate 700, at least one chip structure PS, and a processor chip 800. The chip structure PS may be configured substantially the same as any of the semiconductor packages 10, 10a, 10b, 10c, 10d, 10e, 10f, and 10g described with reference to FIGS. 1 to 7.

The package substrate 900 may be a support substrate on which the interposer substrate 700, the processor chip 800, and the chip structure PS are mounted, and may be a substrate for a semiconductor package including a printed circuit board (PCB), a ceramic substrate, a glass substrate, a tape interconnection substrate, or the like. The body of the package substrate 900 may include different materials depending on the type of the substrate. For example, when the package substrate 900 is configured as a printed circuit board, the package substrate 900 may be in the form of a body copper-clad laminate or an interconnection layer further stacked on one side or both sides of the copper-clad laminate.

The package substrate 900 may include lower terminals 912, upper terminals 911, and a redistribution circuit 913. The upper terminals 911, the lower terminals 912, and the redistribution circuit 913 may form electrical paths connecting the lower surface to the upper surface of the package substrate 900. The upper terminals 911, the lower terminals 912, and the redistribution circuit 913 may include a metal material, for example, at least one metal selected from a group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy including two or more metals. External connection terminals 920 connected to the lower terminals 912 may be disposed on a lower surface of the package substrate 900. The external connection terminals 920 may include tin (Sn), indium (In), bismuth (Bi), antimony SB, copper (Cu), silver (Ag), zinc (Zn), lead (Pb), and/or an alloy thereof.

The interposer substrate 700 may include a substrate 701, a lower protective layer 703, lower pads 705, an interconnection structure 710, metal bumps 720, and through-vias 730. The chip structure PS and the processor chip 800 may be electrically connected to each other through the interposer substrate 700.

The substrate 701 may be formed of, for example, one of a silicon, an organic, a plastic, and a glass substrate. When the substrate 701 is configured as a silicon substrate, the interposer substrate 700 may be referred to as a silicon interposer. Differently from the example in the drawings, when the substrate 701 is configured as an organic substrate, the interposer substrate 700 may be referred to as a panel interposer.

A lower protective layer 703 may be disposed on a lower surface of the substrate 701, and lower pads 705 may be disposed below the lower protective layer 703. The lower pads 705 may be connected to through-vias 730. The chip structure PS and processor chip 800 may be electrically connected to the package substrate 900 through metal bumps 720 disposed below the lower pads 705.

An interconnection structure 710 may be disposed on an upper surface of the substrate 701, and may include an interlayer insulating layer 711 and a single-layer or multilayer interconnection structure 712. When the interconnection structure 710 is configured as a multilayer interconnection structure, interconnection patterns on different layers may be connected to each other through contact vias.

The through-vias 730 may extend from an upper surface of the substrate 701 to a lower surface and may penetrate the substrate 701. Also, the through-vias 730 may extend into the interconnection structure 710 and may be electrically connected to interconnections of the interconnection structure 710. When the substrate 701 is silicon, the through-via 730 may be referred to as a TSV. In example embodiments, the interposer substrate 700 may include only the interconnection structure internally and may not include the through-via.

The interposer substrate 700 may be used for converting or transferring an input electrical signal between the package substrate 900 and the chip structure PS or the processor chip 800. Accordingly, the interposer substrate 700 may not include devices such as active devices or passive devices. Also, in the example embodiment, the interconnection structure 710 may be disposed in a lower portion of the through-vias 730. For example, the position relationship between the interconnection structure 710 and the through-vias 730 may be relative.

The metal bumps 720 may electrically connect the interposer substrate 700 to the package substrate 900. The chip structures PS may be electrically connected to the metal bumps 720 through the interconnections of the interconnection structure 710 and the through-via 730. Accordingly, in the example embodiment, lower pads 705 used for power or ground may be integrated and connected together to the metal bump 720, such that the number of the lower pads 705 may be greater than the number of the metal bumps 720.

The processor chip 800 may include, for example, a central processor (CPU), a graphics processor (GPU), a field programmable gate array (FPGA), a digital signal processor (DSP), an encryption processor, a microprocessor, a microcontroller, an analog-to-digital converter, an application-specific integrated circuit (ASIC), or the like. Connection bumps 850 may be disposed below the processor chip 800.

In an example embodiment, the semiconductor package 10h may further include an internal encapsulant covering the chip structure PS and the processor chip 800 on the interposer substrate 700. Also, the semiconductor package 10h may further include an external encapsulant covering the interposer substrate 700 and the internal encapsulant on the package substrate 900. The external encapsulant and the internal encapsulant may be formed together and may not be distinguished from each other. In example embodiments, the semiconductor package 10h may further include a heat dissipation structure covering the chip structure PS and the processor chip 800.

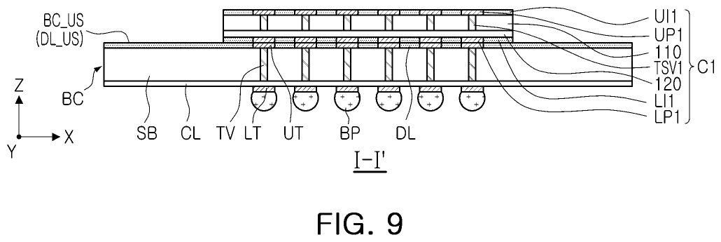

FIGS. 9 to 12 are cross-sectional diagrams illustrating processes of a method of manufacturing a semiconductor package in order according to an example embodiment.

Referring to FIG. 9, a first semiconductor chip C1 may be formed on a base chip BC.

A base chip BC including a substrate SB, a circuit layer CL, lower connection terminals LT and upper connection terminals UT opposite to each other, an upper protective layer DL surrounding a side surface of each of the upper connection terminals UT on the substrate SB, and through-vias TV electrically connecting the lower connection terminals LT to the upper connection terminals UT may be provided. A plurality of connection bumps BP may be attached to a lower portion of the base chip BC. The base chip BC may be temporarily attached to a carrier (not illustrated) by an adhesive material layer (not illustrated).

A planarization process may be applied to the base chip BC. Accordingly, a flat surface (flat surface) BC_US provided for ‘direct bonding’ may be formed.

A first semiconductor chip C1 may be formed on the base chip BC. The first semiconductor chip C1 may be understood to include components described with reference to FIGS. 1 to 2C. The first semiconductor chip C1 may be directly bonded to the base chip BC by metal-to-metal bonding and dielectric-to-dielectric bonding (hereinafter referred to as ‘direct bonding’) without a conductive member (e.g., solder bump, copper pillar, or the like) for electrical connection.

Similarly, a planarization process may be applied to the first semiconductor chip C1 to provide a flat surface provided for ‘direct bonding.’

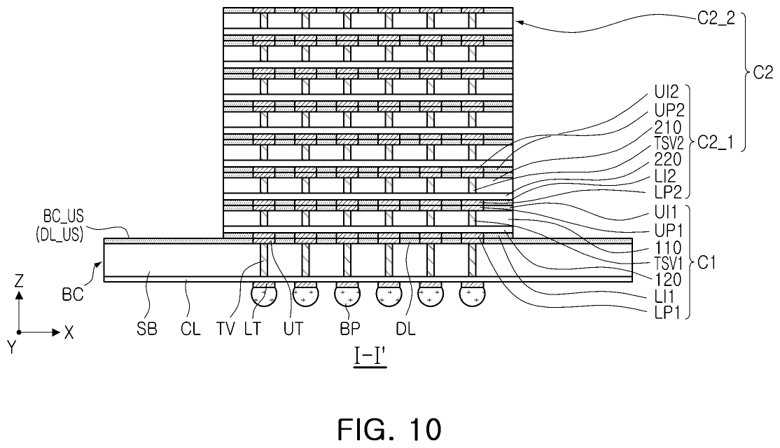

Referring to FIG. 10, at least one second semiconductor chip C2 may be formed on the first semiconductor chip C1.

At least one second semiconductor chip C2 may be formed on the first semiconductor chip C1. At least one second semiconductor chip C2 may be understood to include components described with reference to FIGS. 1 to 2C. At least one second semiconductor chip C2 may be directly bonded to the first semiconductor chip C1 by metal-to-metal bonding and dielectric-to-dielectric bonding (hereinafter referred to as ‘direct bonding’) without a conductive member (e.g., solder bump, copper pillar, or the like) for electrical connection.

When a plurality of the second semiconductor chips C2 are provided, it may be understood that a lowermost second-first semiconductor chip C2_1 and an uppermost second-second semiconductor chip C2_2 may be formed on the first semiconductor chip C1.

Similarly to the example described with reference to FIG. 9, a planarization process may be applied to each of the plurality of second semiconductor chips C2 to provide a flat surface provided for ‘direct bonding.’

Referring to FIG. 11, a third semiconductor chip C3 may be formed on the second semiconductor chip C2.

A third semiconductor chip C3 having a first adhesive layer 401 attached to the back surface C3_BS thereof may be formed on the second semiconductor chip C2. The third semiconductor chip C3 may be understood to include components described with reference to FIGS. 1 to 2C. Alternatively, the third semiconductor chip C3 may be understood to include components described with reference to FIG. 4.

The third semiconductor chip C3 may be directly bonded to the second semiconductor chip C2 (or second-second semiconductor chip C2_2) by metal-to-metal bonding and dielectric-to-dielectric bonding (hereinafter referred to as ‘direct bonding’) without a conductive member (e.g., solder bump, copper pillar, or the like) for electrical connection.

Referring to FIG. 12, a dummy chip DC may be formed on the third semiconductor chip C3.

A dummy chip DC having a second adhesive layer 402 attached to the front surface DC_FS thereof may be formed on the third semiconductor chip C3. The dummy chip DC may be formed on the third semiconductor chip C3 such that the second adhesive layer 402 may be formed on the first adhesive layer 401.

Thereafter, adhesive strength of the first and second adhesive layers 401 and 402 may be formed through a thermal compression process.

In example embodiments, the thermal compression process may be performed under relatively low pressure and low temperature conditions as compared to a general thermal compression process performed after directly forming an adhesive layer formed on the front surface of the dummy chip on the back surface of the semiconductor chip. In example embodiments, sufficient adhesive strength may be formed on the first and second adhesive layers 401 and 402 even by the thermal compression process under relatively low pressure and low temperature conditions.

Thereafter, a plurality of chip stack CS, a plurality of adhesive layers 401 and 402 and an encapsulant ML covering a side surface of each of the dummy chip DC may be formed on the base chip BC.

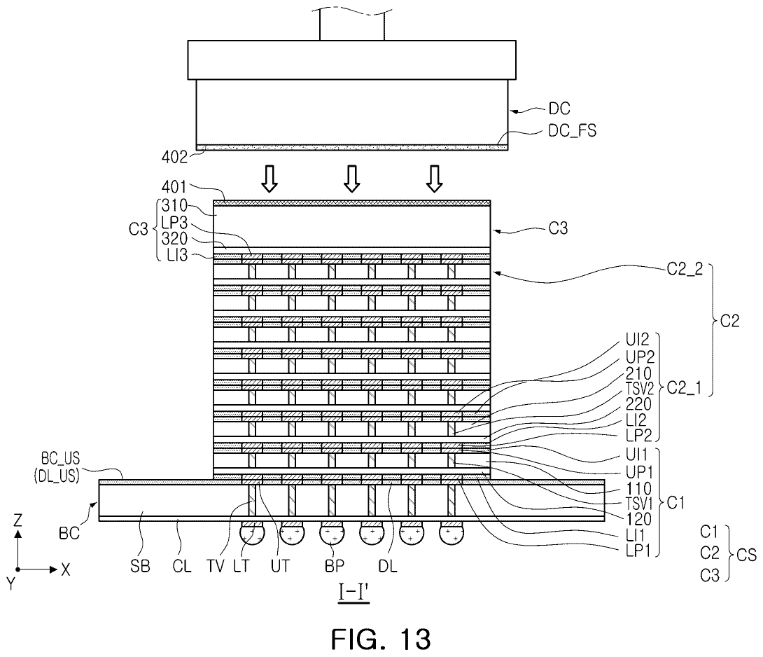

FIG. 13 is a cross-sectional diagram illustrating processes of a method of manufacturing a semiconductor package in order according to an example embodiment. FIG. 13 may be a process diagram continuing from FIG. 11.

Referring to FIG. 13, a dummy chip DC may be formed on a third semiconductor chip C3.

A dummy chip DC having a second adhesive layer 402 attached to the front surface DC_FS thereof and having a first width W1 may be formed on a third semiconductor chip C3 having a second width W2 greater than the first width W1. Accordingly, at least a portion of a lower surface of the second adhesive layer 402 may be exposed.

Thereafter, a plurality of chip stack CS, a plurality of adhesive layers 401 and 402, and an encapsulant ML covering each side surface of the dummy chips DC may be formed on the base chip BC. The encapsulant ML may cover the lower surface of the second adhesive layer 402 of which at least a portion is exposed.

According to the aforementioned example embodiments, a semiconductor package having improved reliability and a method for manufacturing the same may be provided.

Also, by disposing a plurality of adhesive layers between a semiconductor chip stack and a dummy chip, cohesion force between a base chip and an encapsulant may be improved, and accordingly, a semiconductor package having improved reliability may be provided.

While the example embodiments have been illustrated and described above, it will be configured as apparent to those skilled in the art that modifications and variations could be made without departing from the scope of the present disclosure as defined by the appended claims.

What is claimed is:

1. A semiconductor package, comprising:
a base chip including lower connection terminals and upper connection terminals opposite to each other, and through-electrodes electrically connecting the lower connection terminals to the upper connection terminals;
a semiconductor chip stack including a plurality of semiconductor chips stacked in order on the base chip in a first direction, wherein the plurality of semiconductor chips in the semiconductor chip stack comprise:
a first semiconductor chip disposed on the base chip, the first semiconductor chip including first lower pads and first upper pads opposite to each other, and first through-vias electrically connecting the first lower pads to the first upper pads,
a second semiconductor chip disposed on the first semiconductor chip, the second semiconductor chip including second lower pads and second upper pads opposite to each other, and including second through-vias electrically connecting the second lower pads to the second upper pads,
a third semiconductor chip disposed on the second semiconductor chip, the third semiconductor chip including front pads disposed on a front surface of the third semiconductor chip;
a plurality of connection bumps disposed below the base chip and electrically connected to the lower connection terminals;
a dummy chip on the semiconductor chip stack; and
a plurality of adhesive layers between the semiconductor chip stack and the dummy chip,
wherein the first lower pads of the first semiconductor chip are in contact with the upper connection terminals of the base chip adjacent to each other in the first direction,
wherein the first upper pads of the first semiconductor chip are in contact with the second lower pads of the second semiconductor chip adjacent to each other in the first direction,
wherein the front pads of the third semiconductor chip are in contact with the second upper pads of the second semiconductor chip adjacent to each other in the first direction, and
wherein the plurality of adhesive layers includes a first adhesive layer on the semiconductor chip stack and a second adhesive layer on the first adhesive layer.

2. The semiconductor package of claim 1,
wherein the first adhesive layer includes a first protrusion that protrudes beyond a side surface of the third semiconductor chip, and
wherein the second adhesive layer includes a second protrusion that protrudes beyond a side surface of the dummy chip.

3. The semiconductor package of claim 2, wherein a lower region of the second protrusion and an upper region of the first protrusion are in contact with each other.

4. The semiconductor package of claim 2, wherein a boundary region is defined between the first protrusion and the second protrusion.

5. The semiconductor package of claim 4, wherein the boundary region is a concave region formed between an end of the first protrusion and an end of the second protrusion.

6. The semiconductor package of claim 2,
wherein at least a portion of the first protrusion extends toward an upper surface of the base chip, and
wherein the at least the portion of the first protrusion is in contact with a side surface of the third semiconductor chip.

7. The semiconductor package of claim 2,
wherein at least a portion of the second protrusion extends in the first direction, and
wherein the at least the portion of the second protrusion is in contact with the side surface of the dummy chip.

8. The semiconductor package of claim 1,
wherein the first adhesive layer includes a first portion having a width smaller than a width of the third semiconductor chip,
wherein the second adhesive layer includes:
a second portion having a second-first portion between the first portion and the dummy chip and a second-second portion connected to the second-first portion and covering a side surface of the first portion; and
a protrusion connected to the second portion and protruding from a side surface of the semiconductor chip stack and the dummy chip.

9. The semiconductor package of claim 8, wherein the protrusion of the second adhesive layer is in contact with the side surface of the semiconductor chip stack and the side surface of the dummy chip.

10. The semiconductor package of claim 1, wherein the plurality of adhesive layers includes a third adhesive layer between the first adhesive layer and the second adhesive layer.

11. The semiconductor package of claim 1, wherein a width of the dummy chip is greater than a width of the semiconductor chip stack.

12. The semiconductor package of claim 11,
wherein the first adhesive layer includes a first extension portion on an upper surface of the third semiconductor chip, and a first protrusion connected to the first extension portion and protruding beyond a side surface of the third semiconductor chip, and
wherein the second adhesive layer includes a second extension portion on a lower surface of the dummy chip, and a second-first protrusion protruding downwardly from a lower surface of the second extension portion and in contact with the first protrusion.

13. The semiconductor package of claim 12,
wherein the second adhesive layer further includes a second-second protrusion protruding from a side surface and a lower surface of an end of the second extension portion, and
wherein at least a portion of the second-second protrusion is in contact with a side surface of the dummy chip.

14. A semiconductor package, comprising:
a base chip;
a semiconductor chip stack including a plurality of semiconductor chips stacked in order on the base chip in a first direction;
a dummy chip on the semiconductor chip stack;
an adhesive layer between the semiconductor chip stack and the dummy chip; and
an encapsulant covering a side surface of each of the semiconductor chip stack, the dummy chip, and the adhesive layer on the base chip,
wherein the adhesive layer includes an extension portion extending in a second direction perpendicular to the first direction between the semiconductor chip stack and the dummy chip and a plurality of fillet portions connected to the extension portion and extending to the encapsulant,
wherein the plurality of fillet portions include:
a first fillet portion extending from a lower region of the extension portion into the encapsulant; and
a second fillet portion extending from an upper region of the extension portion into the encapsulant.

15. The semiconductor package of claim 14,
wherein the first and second fillet portions are in contact with each other, and
wherein a boundary region is defined between an end of the first fillet portion and an end of the second fillet portion.

16. The semiconductor package of claim 14,
wherein the first fillet portion is in contact with the side surface of the semiconductor chip stack, and
wherein the second fillet portion is in contact with the side surface of the dummy chip.

17. The semiconductor package of claim 16, wherein an area in which the first fillet portion is in contact with the side surface of the semiconductor chip stack is greater than an area in which the second fillet portion is in contact with the side surface of the dummy chip.

18. The semiconductor package of claim 14, wherein a maximum width in a horizontal direction of the first fillet portion is greater than a maximum width in the horizontal direction of the second fillet portion.

19. A semiconductor package, comprising:
a base chip including a base substrate and upper connection terminals disposed in an upper portion of the base substrate;
a semiconductor chip stack including a plurality of semiconductor chips stacked in order on the base chip in a first direction, each of the plurality of semiconductor chips including lower and upper pads opposite to each other and having through-vias electrically connecting the lower pads to the upper pads, wherein the plurality of semiconductor chips include a lowermost semiconductor chip and an uppermost semiconductor chip, and the lower pads of the lowermost semiconductor chip are in contact with the upper connection terminals;
a dummy chip on the semiconductor chip stack; and
a plurality of adhesive layers including a first adhesive layer on the uppermost semiconductor chip and a second adhesive layer on the first adhesive layer.

20. The semiconductor package of claim 19, further comprising:
an encapsulant covering a side surface of each of the plurality of semiconductor chips on the base chip, a side surface of the dummy chip, and a side surface of each of the plurality of adhesive layers,
wherein the first adhesive layer includes a first fillet portion extending into the encapsulant, and
wherein the second adhesive layer includes a second fillet portion extending into the encapsulant and in contact with an upper region of the first fillet portion.
